(19) United States
(12) Patent Application Publication
(10) Pub. No.: US 2022/0416453 A1
(43) Pub. Date: Dec. 29, 2022

(54) HEADER CONNECTOR PIN ARRANGEMENT

(71) Applicant: Ford Global Technologies, LLC, Dearborn, MI (US)

(72) Inventor: Benjamin A. Tabatowski-Bush, Ann Arbor, MI (US)

(21) Appl. No.: 17/362,439

(22) Filed: Jun. 29, 2021

(51) Int. Cl. H01R 11/28; H01R 12/71; H01R 13/514; H01R 13/20

(52) U.S. Cl. CPC H01R 11/281; H01R 12/716; H01R 13/514; H01R 13/20; H01R 2201/26

(57) ABSTRACT

A header connector includes a body, a staggered column of L-shaped connector pins of two different lengths extending in a same direction from a first side of the body, and a staggered column of mating pins on a second side of the body opposite the first side. Each one of the mating pins is connected with one of the connector pins.

### TECHNICAL FIELD

This disclosure relates to automotive electronic circuitry.

### BACKGROUND

An alternatively powered vehicle may include a traction battery arranged to provide power to an electric machine. The electric machine may transform electrical energy from the traction battery to mechanical energy to move wheels of the vehicle. The electric machine may also transform mechanical energy from the wheels to electrical energy for storage in the traction battery.

Various electrical components are used to facilitate such electrical energy transfer, and support related control and monitoring functions. Electrical connectors are one class of electrical components, and can include pins molded into a plastic base. The pins may be in a single row or multiple rows. And, the pins may be straight or bent depending on the application and environment in which they are used.

### SUMMARY

An automotive battery pack sensing module includes a printed circuit board defining an aligned set of far metal pads and an aligned set of near metal pads. The sets of metal pads are arranged in a staggered column. The automotive battery pack sensing module also includes a header connector on the circuit board that has extending therefrom an aligned set of long connector pins bonded to the far metal pads and an aligned set of short connector pins bonded to the near metal pads. The sets of connector pins are arranged in a staggered column.

The header connector may have mating pins arranged in a staggered column on a side opposite the sets of connector pins. The mating pins may be male or female. Each of the long connector pins and short connector pins may be L-shaped. The sets of connector pins may extend through the printed circuit board. The sets of connector pins may be surface mounted to the printed circuit board. The sets of connector pins may be energized at all times. The metal pads may be copper pads.

A header connector includes a body, a staggered column of L-shaped connector pins of two different lengths extending in a same direction from a first side of the body, and a staggered column of mating pins on a second side of the body opposite the first side. Each one of the mating pins is connected with one of the connector pins.

Some of the connector pins may have a length greater than other of the connector pins. Some of the connector pins may define a first aligned set of connector pins, and other of the connector pins may define a second aligned set of connector pins. Members of the first and second aligned set of connector pins may occupy alternating positions in the staggered column. The body may be plastic.

An electronic assembly includes a header connector having a body and a staggered column of L-shaped connector pins extending in a same direction away from the body, and a printed circuit board supporting the header connector and defining a staggered column of connection points bonded with the staggered column of L-shaped connector pins.

The L-shaped connector pins may be of two different lengths. The header connector may further have a staggered column of mating pins connected to the L-shaped connector pins. The mating pins may be disposed on a side of the body opposite the L-shaped connector pins. The mating pins may be male or female. The connection points may be metal pads. The L-shaped connector pins may extend through the printed circuit board. The L-shaped connector pins may be surface mounted to the printed circuit board.

### BRIEF DESCRIPTION OF THE DRAWINGS

FIG. 1 is a perspective view of a header connector.

FIG. 2 is a plan view of a printed circuit board with aligned metal pads.

FIG. 3 is a perspective view of another header connector.

FIG. 4 is a plan view of another printed circuit board with staggered metal pads.

FIG. 5 is a perspective view of a printed circuit board and header connector assembly.

FIG. 6 is a side view of the header connector of FIG. 5.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Here, we consider the design of voltage cell sense lead connectors on battery pack sensing modules, which, in some scenarios, connect terminals of lithium cells from a traction battery pack to the battery pack sensing modules. The battery pack sensing modules each contain a battery monitoring integrated circuit, and perform functions of measuring cell voltages for lithium batteries of an electrified vehicle, measuring temperatures from arrays of these lithium cells, cell balancing, and measuring array voltage (also called the brick voltage) which, when summed with other array voltages from the entire battery pack, defines the pack voltage in an updated version of battery electronics.

Newer versions of battery electronics are more distributed than prior versions, because the measurement electronics for the cells and arrays are in small battery pack sensing modules, which are co-located with the cells in an array. Certain prior technologies would locate the battery electronics in one centralized module, for example, with a large wire harness to carry the voltage cell sense leads from the lithium cells to the battery electronics. Newer approaches allow methods of electrical distribution systems to carry signals from the lithium cells to the measurement circuits. Instead of having to rely upon a round-wire harness, it now becomes possible to use a flexible printed circuit board to connect from the cell terminals to the battery pack sensing module. Specifically, we consider the case where the array electrical distribution system is arranged with a flexible printed circuit board that connects to the cell terminals, and carries the signals to a flying connector which is intended to connect to the battery pack sensing module input nodes.

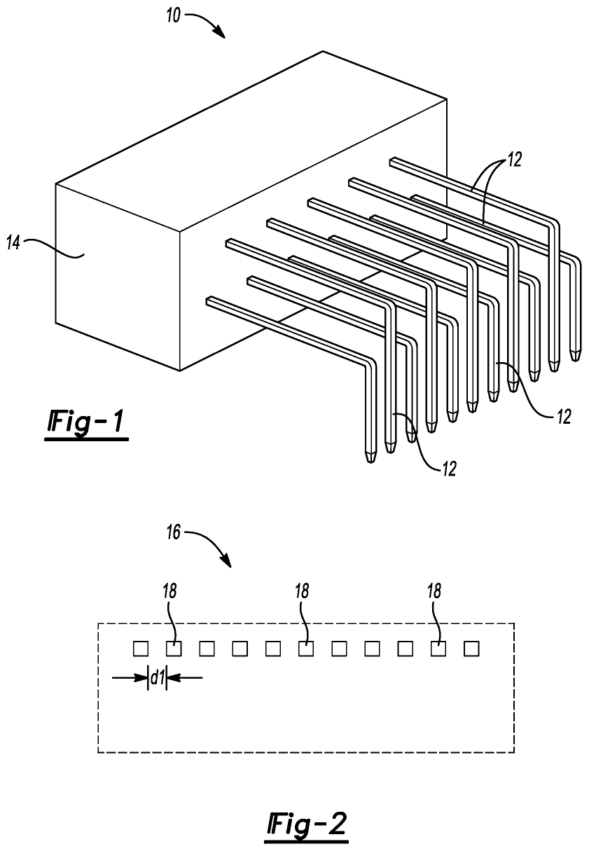

Referring to FIG. 1, a battery pack sensing module previously may have had a surface mounted connector header 10 for its voltage cell sense leads 12, which extend from a same side of body 14. This is a typical style of lead forming for surface mount connectors. Notice that even for a two-row connector, which is common in the automotive industry to optimize cost and pin density, the connector leads 12 are brought back behind the body 14 and lead-formed in a way to bring the surface mount leads 12 all in line with each other, with all the leads 12 spaced tightly.

Referring to FIGS. 1 and 2, a printed circuit board 16 corresponding to the connector header 10 has a row of copper pads 18. Each of the leads 12 can be surface mounted to one of the copper pads 18. Aligning ends of the leads 12 and the copper pads 18 can simplify the handling and surface mount device placement activities. The dimension d1 is effectively the pin spacing. For certain connectors, the dimension d1 can be small, e.g., half a millimeter. The voltage rating for this type of tight pin spacing may thus be about 10V. Since lithium cells are about 4V each, it may suffice for some scenarios. In certain circumstances however, tight spacing may create more opportunities for dendritic growth and manufacturing issues, such as solder balls or metallic contamination, that may short adjacent pins.

Some connectors, e.g., battery pack sensing module header connectors, may be energized continuously for years. Maximizing pin spacing may thus be desirable to allow for higher voltage ratings for the pins and act as a margin against the above mentioned issues. It may also maximize the creepage and clearance for the connector.

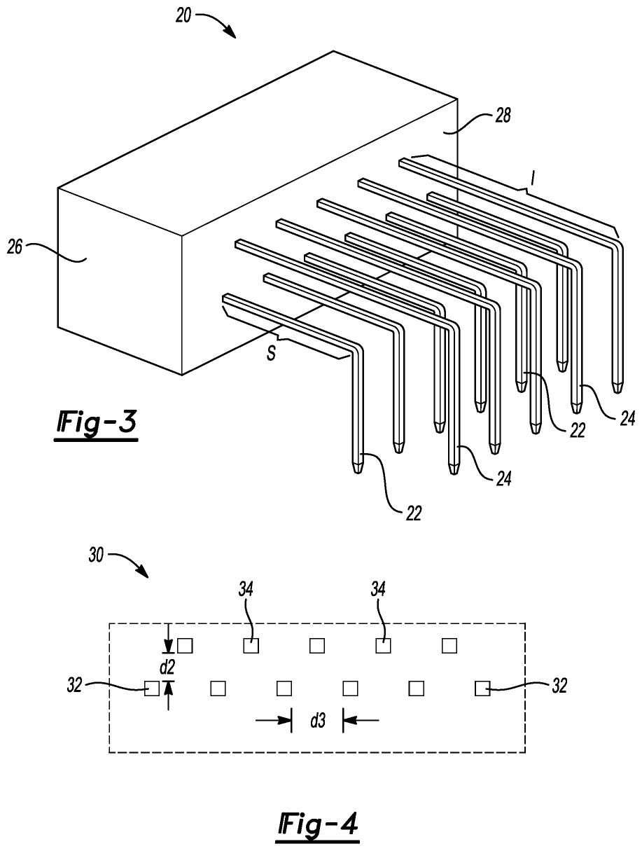

Referring to FIG. 3, a surface mounted connector header 20 includes shorter and longer L-shaped voltage cell sense leads 22, 24 arranged in a staggered column, and which extend in a same direction away from plastic body 26. The shorter leads 22 have a portion, s, that extends generally perpendicularly away from face 28 of the body 26 before bending. The longer leads 24 have a portion, l, that extends generally perpendicularly away from the face 28 before bending. Thus, every other of the leads 22, 24 of the staggered column is brought out further away from the body 26.

Referring to FIGS. 3 and 4, a printed circuit board 30 corresponding to the connector header 20 has near and far copper pads 32, 34 arranged in a staggered column. The shorter leads 22 are surface mounted to the near copper pads 32. The longer leads 24 are surface mounted to the far copper pads 34. Instead of having all the solder pads aligned as in FIG. 2, they are now spaced apart with a separation distance d2. Moreover, the separation distance d3 between adjacent near copper pads 32 and adjacent far copper pads 34 can be greater than the separation distance d2. The voltage rating achievable with this additional separation could be, in certain examples, 200V. This is noticeably more than that associated with FIGS. 1 and 2.

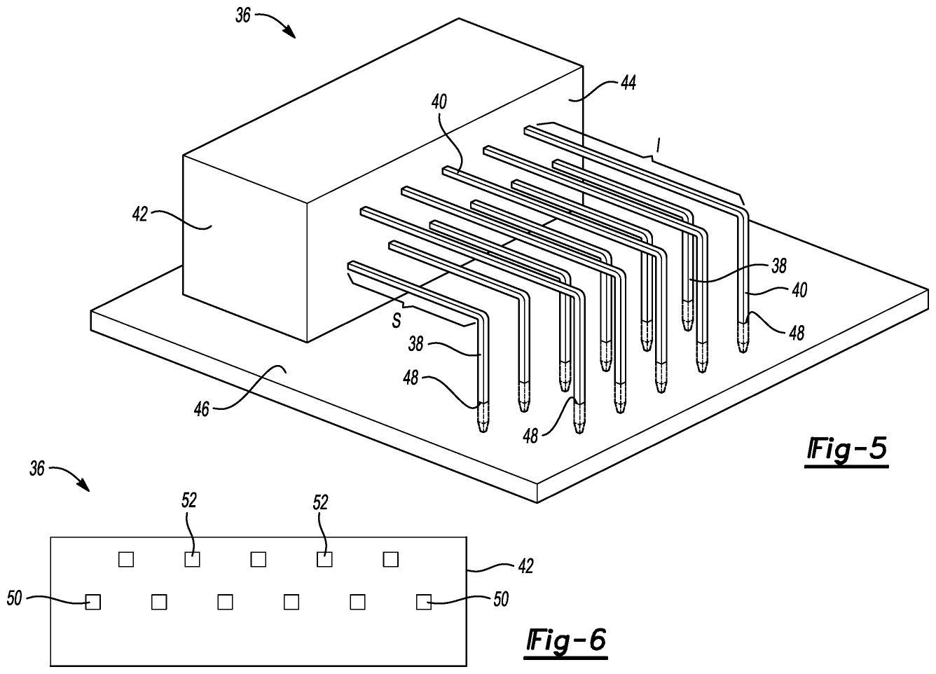

Referring to FIG. 5, a connector header 36 includes shorter and longer voltage cell sense leads 38, 40 arranged in a staggered column, and which extend in a same direction away from body 42. The shorter leads 38 have a portion, s, that extends generally perpendicularly away from face 44 of the body 42 before bending. The longer leads 40 have a portion, l, that extends generally perpendicularly away from the face 44 before bending.

Printed circuit board 46 supports the connector header 36, and the shorter and longer leads 38, 40 extend through staggered holes 48 in the printed circuit board 46. Near and far copper pads of the printed circuit board are thus on a side thereof opposite the connector header 36.

Referring to FIG. 6, the connector header 36 includes mating pins 50, 52 arranged in a staggered column on face 54 of the body 42, which is opposite the face 44. The mating pins 50 are connected with the shorter leads 38 and the mating pins 52 are connected with the longer leads 40. The mating pins 50, 52 may be male or female.

As mentioned above, the components contemplated herein may be used within the context of automotive electronics to, for example, increase the voltage rating associated with connector headers, with the potential benefit of increasing the lifetime of the same. Moreover, increased physical separation between adjacent pins of a header connector may improve its robustness against various operational issues, such as dendritic growth, and improve manufacturability given that bonding operations between the pins and metal pads need not be performed with the same level of precision as pins and pads that are more closely spaced.

While exemplary embodiments are described above, it is not intended that these embodiments describe all possible forms encompassed by the claims. The words used in the specification are words of description rather than limitation, and it is understood that various changes may be made without departing from the spirit and scope of the disclosure.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. An automotive battery pack sensing module comprising:
a printed circuit board defining an aligned set of far metal pads and an aligned set of near metal pads, wherein the sets of metal pads are arranged in a staggered column; and
a header connector on the printed circuit board and having extending therefrom an aligned set of long connector pins bonded to the far metal pads and an aligned set of short connector pins bonded to the near metal pads, wherein the sets of connector pins are arranged in a staggered column.

2. The automotive battery pack sensing module of claim 1, wherein the header connector has mating pins arranged in a staggered column on a side opposite the sets of connector pins.

3. The automotive battery pack sensing module of claim 2, wherein the mating pins are male or female.

4. The automotive battery pack sensing module of claim 1, wherein each of the long connector pins and short connector pins is L-shaped.

5. The automotive battery pack sensing module of claim 1, wherein the sets of connector pins extend through the printed circuit board.

6. The automotive battery pack sensing module of claim 1, wherein the sets of connector pins are surface mounted to the printed circuit board.

7. The automotive battery pack sensing module of claim 1, wherein the sets of connector pins are energized at all times.

8. The automotive battery pack sensing module of claim 1, wherein the metal pads are copper pads.

9. A header connector comprising:
a body;
a staggered column of L-shaped connector pins of two different lengths extending in a same direction from a first side of the body; and
a staggered column of mating pins on a second side of the body opposite the first side, wherein each one of the mating pins is connected with one of the connector pins.

10. The header connector of claim 9, wherein some of the connector pins have a length greater than other of the connector pins.

11. The header connector of claim 10, wherein the some of the connector pins define a first aligned set of connector pins, and wherein the other of the connector pins define a second aligned set of connector pins.

12. The header connector of claim 11, wherein members of the first and second aligned set of connector pins occupy alternating positions in the staggered column.

13. An electronic assembly comprising:
a header connector having a body and a staggered column of L-shaped connector pins extending in a same direction away from the body; and
a printed circuit board supporting the header connector and defining a staggered column of connection points bonded with the staggered column of L-shaped connector pins.

14. The electronic assembly of claim 13, wherein the L-shaped connector pins are of two different lengths.

15. The electronic assembly of claim 13, wherein the header connector further has a staggered column of mating pins connected to the L-shaped connector pins.

16. The electronic assembly of claim 15, wherein the mating pins are disposed on a side of the body opposite the L-shaped connector pins.

17. The electronic assembly of claim 15, wherein the mating pins are male or female.

18. The electronic assembly of claim 13, wherein the connection points are metal pads.

19. The electronic assembly of claim 13, wherein the L-shaped connector pins extend through the printed circuit board.

20. The electronic assembly of claim 13, wherein the L-shaped connector pins are surface mounted to the printed circuit board.
